(19) United States
(12) Patent Application Publication
(10) Pub. No.: US 2008/0074153 A1
(43) Pub. Date: Mar. 27, 2008

(54) LINE FAULT DETECTION CIRCUIT

(75) Inventor: Katsuhiko Hakomori, Kawasaki (JP)

Correspondence Address: KATTEN MUCHIN ROSENMAN LLP, 575 MADISON AVENUE, NEW YORK, NY, 10022-2585, US

(73) Assignee: FUJITSU LIMITED, Kawasaki-shi (JP)

(21) Appl. No.: 11/858,258

(22) Filed: Sep. 20, 2007

(30) Foreign Application Priority Data
Sep. 25, 2006 (JP) 2006-259780

(51) Int. Cl. H03K 5/1532

(52) U.S. Cl. 327/58

(57) ABSTRACT

A line trouble detecting circuit comprises a peak detecting circuit, a first comparison circuit, a bottom detecting circuit, a bottom detecting circuit, a second comparison circuit, and a signal keeping circuit.

The peak detecting circuit detects a peak voltage of amplitude of the one of the differential signal. The first comparison circuit compares an output of the peak detector and a first reference voltage. The bottom detecting circuit detects bottom voltage of the amplitude of the one of the differential signal. The second comparison circuit compares an output of the bottom detecting circuit and a second reference voltage. The signal keeping circuit keeps a signal from the first comparison circuit or the second comparison circuit.

### BACKGROUND OF THE INVENTION

1. Field of the Invention

The present invention is to be applied to a differential transmission line composed of two transmission lines for which impedance control is required.

2. Description of related Art

In a differential transmission line, the effect of the common mode input noise is reduced by individually transmitting differential signals to two signal lines. An example of a configuration using a differential transmission line is a configuration in which an optical transceiver and a media converter are connected. A media converter is disposed at an input and output port of a router (IP switch) or a bridge (L2 switch). There are configurations in which a media converter and a router or bridge are integrated, and an optical transceiver and a media converter are integrated.

The relationship between an optical transceiver, a differential transmission line, and a transmission apparatus such as a media converter is shown in FIG. 1. An optical transceiver 1, a transmission apparatus 2 such as a media converter, terminating resistors 3a to 3d, transmission lines 4a, 4b, 5a, and 5b, an optical receiving circuit 11, an optical transmitting circuit 12, a light-receiving device 11a, and a light-emitting device 12a are shown.

Light received by the light-receiving device 11a is amplified by the optical receiving circuit 11 and is then output to the transmission lines 4a and 4b as differential signals. A signal having a polarity opposite to that of a signal passing through the transmission line 4a is provided for the transmission line 4b. A differential transmission line 4 is achieved by providing such differential signals for the transmission lines 4a and 4b. The impedance of the transmission line 4a is made to match that of the transmission line 4b by the terminating resistors 3a and 3b and the ground. The impedance-matched transmission lines 4a and 4b are connected to the transmission apparatus 2.

The differential signals output from the transmission apparatus 2 are provided for the impedance-matched transmission lines 5a and 5b. A differential transmission line 5 is composed of the transmission lines 5a and 5b. The impedance matching is performed by the terminating resistors 3a and 3b connected to the transmission lines 5a and 5b and the ground. The differential signals transmitted from the transmission lines 5a and 5b are input into the optical transmitting circuit 12. The transmitting circuit 12 causes the light-emitting device 12a such as a laser to emit light on the basis of the received differential signals.

### SUMMARY OF THE INVENTION

According to an aspect of an embodiment, a line trouble detecting circuit detects a line trouble of a differential pair. The differential pair transmits a differential signal with a first line and a second line earthed via termination resistors, respectively.

The line trouble detecting circuit comprises a peak detecting circuit, a first comparison circuit, a bottom detecting circuit, a second comparison circuit, and a signal keeping circuit. The peak detecting circuit detects a peak voltage of amplitude of the one of the differential signal. The first comparison circuit compares an output of the peak detector and a first reference voltage. The bottom detecting circuit detects bottom voltage of the amplitude of the one of the differential signal. The second comparison circuit compares an output of the bottom detecting circuit and a second reference voltage. The signal keeping circuit keeps a signal from the first comparison circuit or the second comparison circuit.

### BRIEF DESCRIPTION OF THE DRAWINGS

FIG. 1 is a diagram showing a relationship between an optical transceiver, a differential transmission line, and a transmission apparatus.

FIG. 2 is a diagram showing examples of a fault occurring at terminating resistors 3a and 3b disposed between a differential transmission line and the ground.

FIG. 3 is a diagram showing characteristics obtained when a terminating resistor is short-circuited.

FIG. 4 is a diagram showing characteristics obtained when the connection between a terminating resistor and the ground is disconnected.

FIG. 5 is a diagram showing a specific configuration of a line fault detection circuit.

FIG. 6 is a diagram showing a specific configuration of each of peak detecting circuit and an amplitude detection circuit.

FIG. 7 is a diagram showing signal output waveforms of individual blocks included in the line fault detection circuit.

FIG. 8 is a diagram showing signal output waveforms of individual blocks included in the line fault detection circuit.

FIG. 9 is a diagram showing a specific configuration of a line fault detection circuit.

FIG. 10 is a diagram showing characteristics of the line fault detection circuit.

### DETAILED DESCRIPTION OF THE EMBODIMENTS

This embodiment is to be applied to a differential transmission line composed of two transmission lines for which impedance control is required.

It is an object of the embodiment is to provide a technique for detecting a line fault even when the line fault occurs at a terminating resistor that is disposed between a line and the ground so as to achieve impedance matching of a differential transmission line composed of two transmission lines for which impedance control is required.

Embodiments will be described with reference to the accompanying drawings. A configuration according to an embodiment is illustrative, and the present invention is not limited to this configuration.

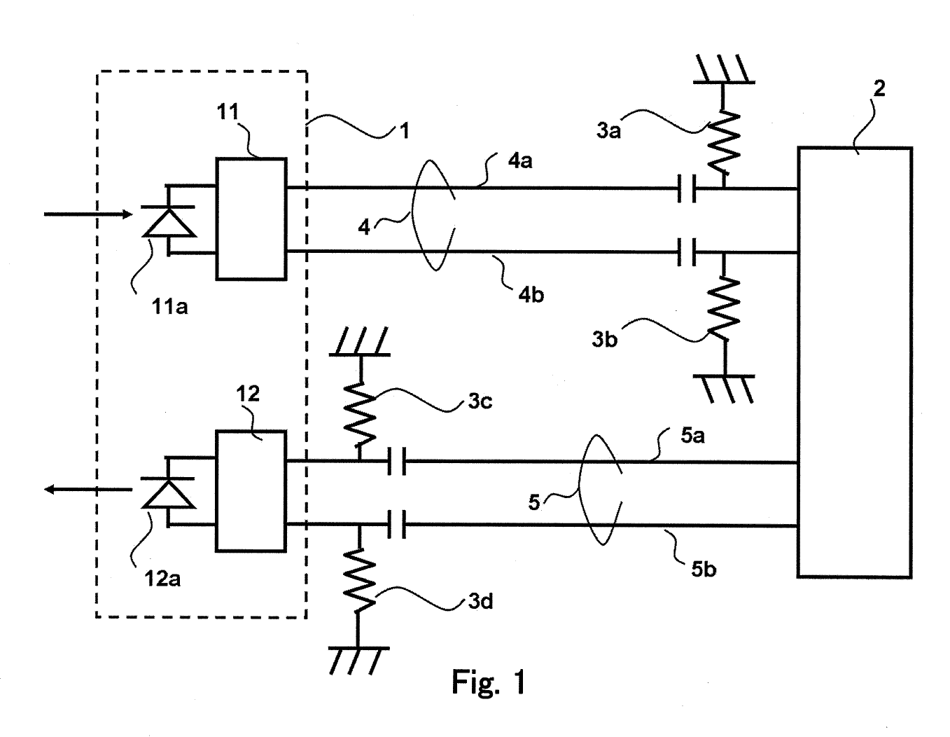

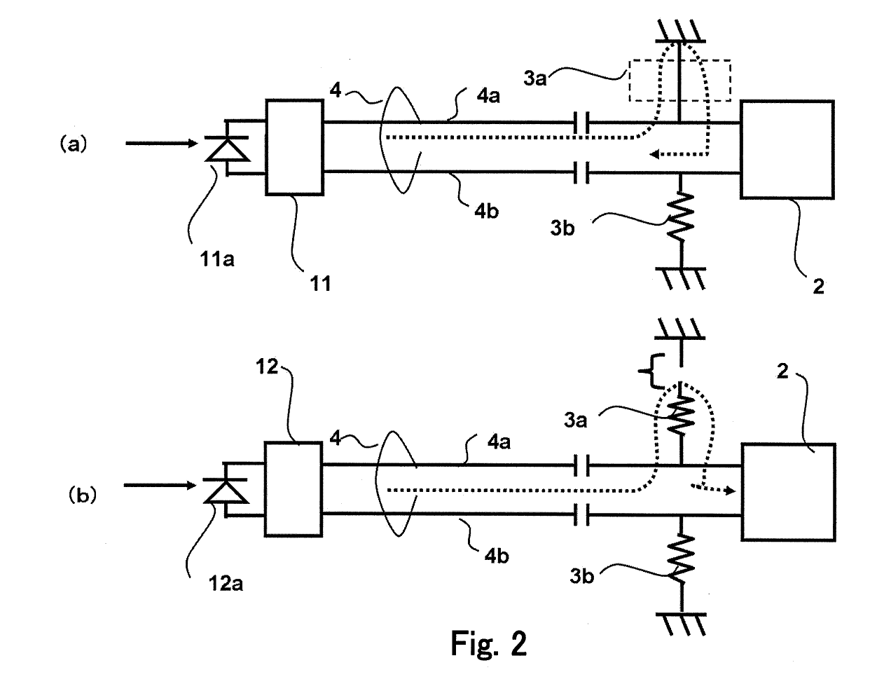

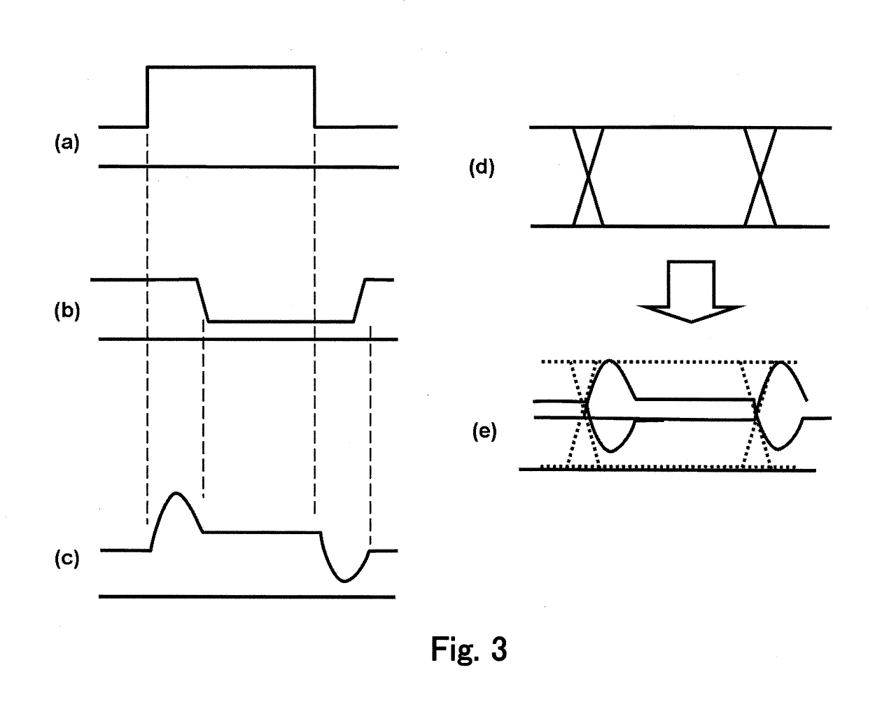

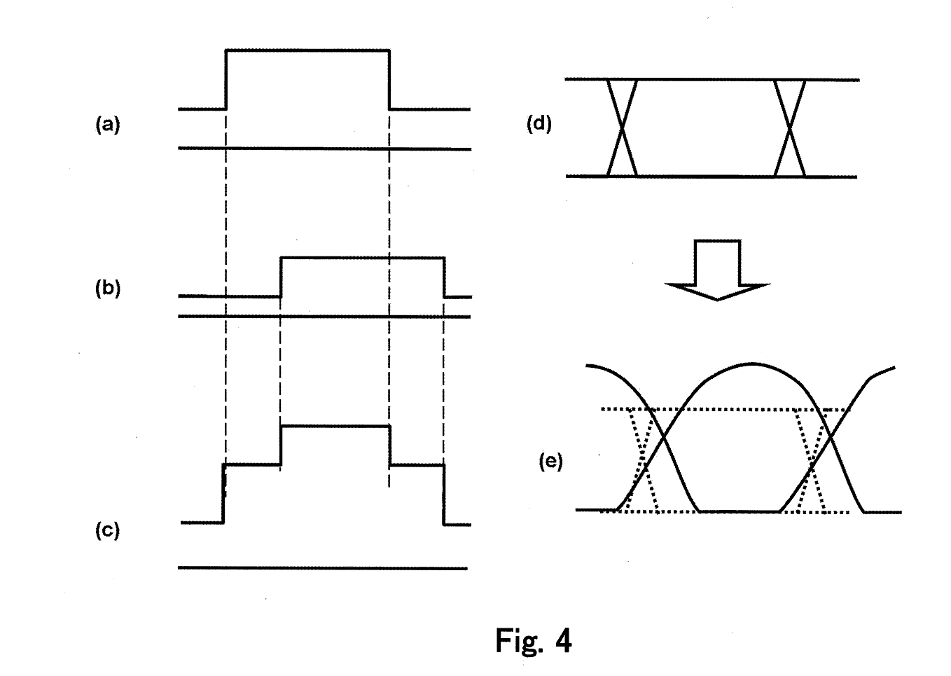

Examples of a fault detected in the present invention will be described with reference to FIGS. 2, 3, and 4. Examples of a fault occurring at the terminating resistors 3a and 3b which are disposed between the differential transmission line and the ground are shown in FIG. 2. In FIG. 2, the same reference numerals are used for components having the same functions as those of FIG. 1 so as to avoid repeated explanation. FIG. 2(a) shows an example in which the terminating resistor 3a is broken and the differential transmission line is directly connected to the ground. FIG. 2(b) shows an example in which the connection between the terminating resistor 3a and the ground is broken at 3c. FIG. 3 shows characteristics obtained when the terminating resistor is short-circuited as shown in FIG. 2(a). FIG. 3(a) shows a signal transmitted from the receiving circuit to the transmission line 4a of the differential transmission line 4 in FIG. 2. FIG. 3(b) shows a state in which a signal whose amplitude is inverted and whose phase is shifted occurs due to signal reflection at the point of the ground. FIG. 3(c) shows a signal input into the transmission apparatus 2 shown in FIG. 2. The signal shown in FIG. 3(c) is a signal obtained by combining the signal shown in FIG. 3(a) which is transmitted through the transmission line 4a and the signal shown in FIG. 3(b) which is returned due to the reflection. FIG. 3(d) shows an eye pattern obtained in a normal state. FIG. 3(e) shows an eye pattern obtained when the terminating resistor 3a is short-circuited as shown in FIG. 2(a). As is apparent from FIGS. 3(c) and 3(e), the entire signal level decreases compared with that of the original signal, and eye apertures are narrowed. Accordingly, the occurrence of such a fault can be detected by detecting a decrease in a peak voltage in the center potion of the eye pattern. FIG. 4 shows characteristics obtained when the connection between the terminating resistor and the ground is broken as shown in FIG. 2(b). FIG. 4(a) shows a signal transmitted from the receiving circuit to the transmission line 4a of the differential transmission line 4 in FIG. 2. FIG. 4(b) shows a state in which a signal whose level decreases at the terminating resistor 3a and whose phase is shifted occurs. FIG. 4(c) shows a signal input into the transmission apparatus 2 shown in FIG. 2. The signal shown in FIG. 4(c) is a signal obtained by combining the signal shown in FIG. 4(a) which is transmitted through the transmission line 4a and the signal shown in FIG. 4(b). FIG. 4(d) shows an eye pattern obtained in a normal state. FIG. 4(e) shows an eye pattern obtained when the connection between the terminating resistor and the ground is broken as shown in FIG. 2(b). As is apparent from FIGS. 4(c) and 4(e), the entire signal level increases compared with that of the original signal, and eye apertures are narrowed due to the change in the phase. Accordingly, the occurrence of such a fault can be detected by detecting an increase in a peak voltage in the center portion of the eye pattern.

### First Embodiment

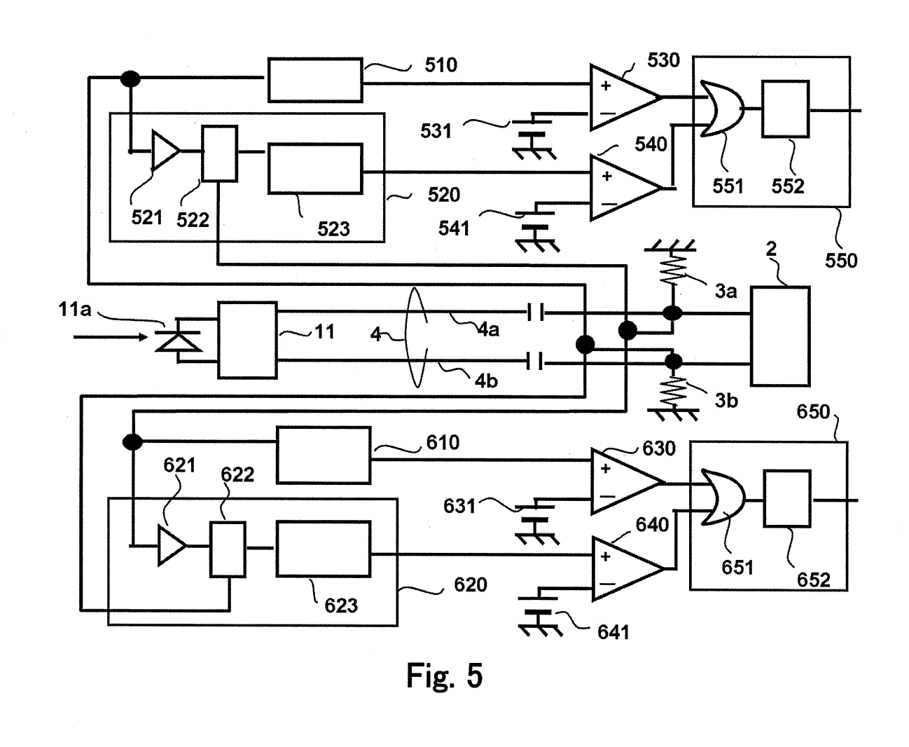

As is apparent from the above-described characteristics of the voltage waveforms, the occurrence of a fault at a terminating resistor can be detected by disposing at an end portion of a differential amplitude transmission line a circuit for detecting whether the level of a voltage in the center portion of an eye pattern is higher or lower than usual. The specific configuration of a line fault detection circuit using the above-described principles is shown in FIG. 5. In FIG. 5, the same reference numerals are used for components having the same functions as those of FIG. 1 so as to avoid repeated explanation. Referring to FIG. 5, a line fault detection circuit 600 for detecting a line fault in a first line of the differential transmission line shown in FIG. 1 and a line fault detection circuit 500 for detecting a line fault in a second line of the differential transmission line shown in FIG. 1 are shown. The line fault detection circuits 500 and 600 have peak detecting circuits 510 and 610, first comparing circuits 530 and 630, trough detecting circuits 520 and 620, second comparing circuits 540 and 640, and signal maintaining circuits 550 and 650, respectively. In the line fault detection circuits 500 and 600, the circuits having the same names have the same functions. Individual circuit will be therefore described in the following using the line fault detection circuit 500.

[Peak Detecting Circuit]

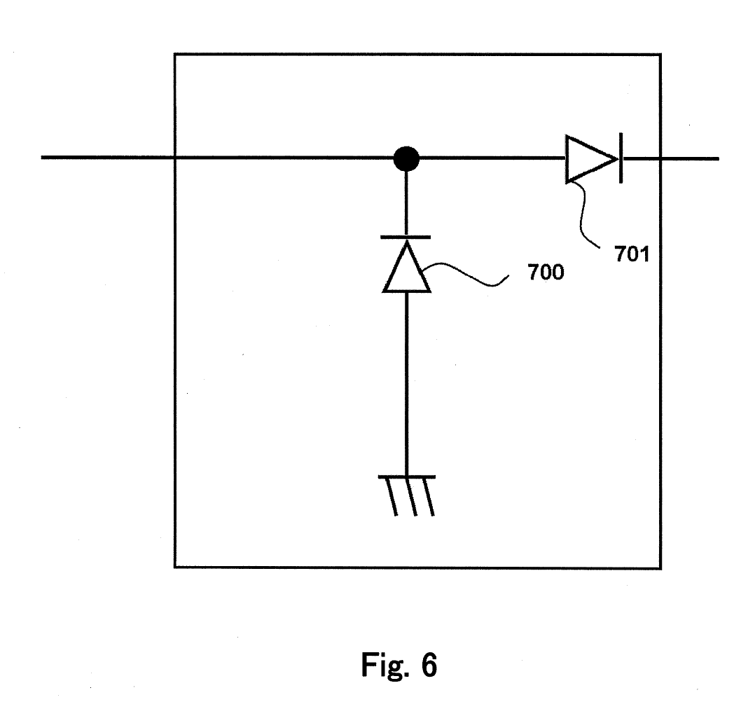

The peak detecting circuit 510 has an input point that is a connection point between the second line and the terminating resistor 3b. The peak detecting circuit 510 removes a bias component included in a signal voltage and outputs a signal amplitude. The specific circuit configuration thereof will be described later with reference to FIG. 6.

[First Comparing Circuit]

The first comparing circuit 530 compares the output of the peak detecting circuit 510 with a first voltage 531 that is a reference voltage. More specifically, the first comparing circuit 530 is configured with an operational amplifier. The output of the peak detecting circuit 510 is input into the non-inverting input terminal of the operational amplifier. The first reference voltage 531 is input into the inverting input terminal of the operational amplifier. When the output of the peak detecting circuit 510 is larger than the value of the first reference voltage 531, a voltage is output from the output terminal of the operational amplifier. The first reference voltage 531 is set to a voltage higher than a voltage output from the optical receiving circuit 11. By performing such a voltage setting, when the fault shown in FIG. 2(b) occurs and the signal shown in FIG. 4 occurs in the second transmission line 4b, it can be determined that a fault has occurred. The output of the first comparing circuit 530 is input into the signal maintaining circuit 550.

[Trough Detecting Circuit]

Like the peak detecting circuit 510, the trough detecting circuit 520 has an input point that is a connection point between the second line and the terminating resistor 3b. The trough detecting circuit 520 includes a signal inverting circuit 521, a switch 522, and an amplitude detection circuit 523. The signal inverting circuit 521 inverts a signal voltage input into the trough detecting circuit 520. The output of the signal inverting circuit 521 is input into the switch 522. The switch 522 passes the output of the signal inverting circuit 521 when the level of a signal passing through the first line is low. Furthermore, the switch 522 interrupts the output of the signal inverting circuit 521 when the level of the signal passing through the first line is high. The output of the switch 522 is input into the amplitude detection circuit 523. The amplitude detection circuit 523 removes a bias component included in the signal voltage output from the switch 522, and outputs a signal amplitude. The specific circuit configuration thereof will be described later with reference to FIG. 6. The output of the amplitude detection circuit 523 is input into the second comparing circuit.

[Second Comparing Circuit]

The second comparing circuit 540 compares the output of the trough detecting circuit 520 (the output of the amplitude detection circuit 523) with a second voltage 541 that is a reference voltage. More specifically, the second comparing circuit 540 is configured with an operational amplifier. The output of the trough detecting circuit 520 is input into the non-inverting input terminal of the operational amplifier. The second reference voltage 541 is input into the inverting input terminal of the operational amplifier. When the output of the trough detecting circuit 520 is higher than the value of the second reference voltage 531, a voltage is output from the output terminal of the operational amplifier. The second reference voltage 541 is set to a voltage lower than a voltage output from the optical receiving circuit 11. By performing such a voltage setting, when the fault shown in FIG. 2(a) occurs and the signal shown in FIG. 3 occurs in the second transmission line 4b, it can be determined that a fault has occurred. The output of the second comparing circuit 540 is input into the signal maintaining circuit 550.

[Signal Maintaining Circuit]

The signal maintaining circuit 550 receives the outputs of the first comparing circuit 530 and the second comparing circuit 540. More specifically, signals output from the first comparing circuit 530 and the second comparing circuit 540 are input into an OR gate 551. The OR gate 551 sets the output thereof to a high level when receiving high-level signals from the first comparing circuit 530 and the second comparing circuit 540. The output of the OR gate 551 is input into a flip-flop circuit 552. The flip-flop circuit 552 maintains the high-level output of the OR gate 551 and transmits the maintained high-level output.

[Peak Detecting Circuit and Amplitude Detection Circuit]

The specific configuration of the peak detecting circuit and the amplitude detecting circuit is shown in FIG. 6. The peak detecting circuit 510 and the amplitude detection circuit 523 are configured with the same circuit. The circuit includes a first diode 700 whose cathode is connected to the input terminal of the peak detecting circuit 510 or the amplitude detection circuit 523 and a second diode 701 whose anode is connected to the input terminal of the peak detecting circuit 510 or the amplitude detection circuit 523. The anode of the first diode 700 is connected to the ground. The cathode of the second diode 701 serves as an output terminal of the peak detecting circuit or the amplitude detection circuit. When a reverse bias is applied to the first diode 700, a bias component included in an input signal voltage is connected to the ground potential, whereby an amplitude value of the input voltage can be obtained as an output voltage value.

[Fault Detection Process in FIG. 2(a)]

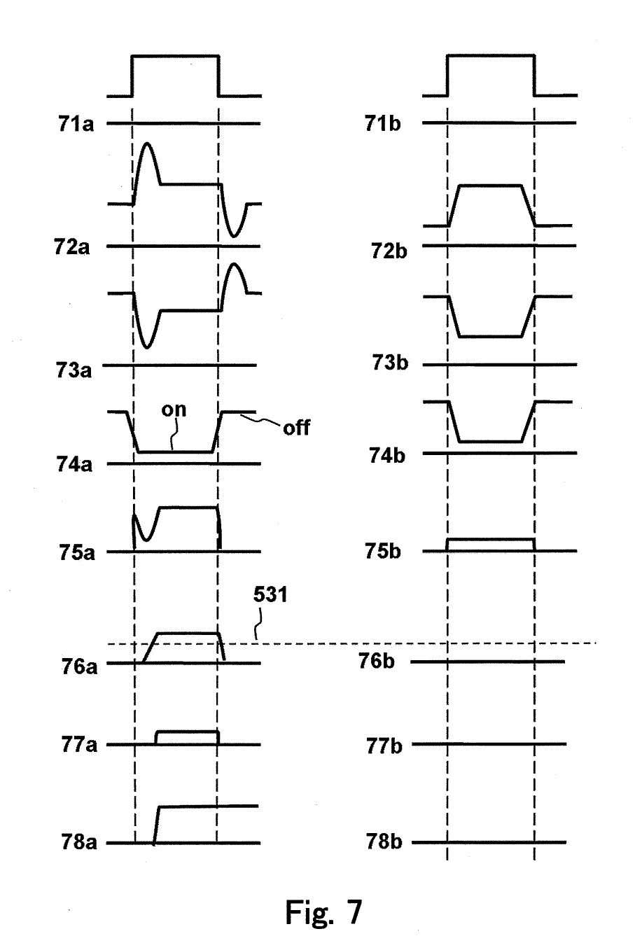

FIG. 7 is a diagram describing a process of detecting the fault shown in FIG. 2(a). Waveforms shown in FIG. 7 will be described using the corresponding blocks shown in FIG. 5. Voltage waveforms 71a to 78a are obtained when the fault shown in FIG. 2(a) occurs.

The voltage waveform 71a is output from the receiving circuit 11. The voltage waveform 72a denotes a voltage at the connection point between the second line and the terminating resistor 3b. The voltage waveform 72a is input into the signal inverting circuit 521 included in the trough detecting circuit 520, so that the voltage waveform 73a is output. The voltage waveform 74a denotes a signal passing through the first line. When the level of the voltage waveform 74a is low, the switch 522 is turned on and a voltage signal is output from the signal inverting circuit 521 to the amplitude detection circuit 523. When the level of the voltage waveform 74a is high, the switch 522 is turned off and no voltage is input into the amplitude detection circuit 523. The waveform 75a denotes a voltage output waveform of the switch 522. A voltage represented by the voltage output waveform 75a is input into the amplitude detection circuit 523. The amplitude detection circuit 523 removes a bias voltage component from the voltage output waveform 75a so as to obtain only an amplitude component and outputs the obtained voltage output waveform 76a. The voltage output waveform 76a is input into the non-inverting input terminal of the second comparing circuit 540. The second comparing circuit 540 compares a voltage represented by the voltage output waveform 76a with the second reference voltage 541, and outputs the voltage output waveform 77a. The voltage output waveform 77a is input into the flip-flop circuit 552 via the OR gate 551. The flip-flop circuit 552 maintains the received signal, and outputs the voltage output waveform 78a.

Voltage waveforms 71b to 78b are obtained when the fault shown in FIG. 2(a) does not occur. The voltage waveform 71b is output from the receiving circuit 11. The voltage waveform 72b denotes a voltage at the connection point between the second line and the terminating resistor 3b. The voltage waveform 72b is input into the signal inverting circuit 521 included in the trough detecting circuit 520, so that the voltage waveform 73b is output. The voltage waveform 74b denotes a signal passing through the first line. When the level of the voltage waveform 74b is low, the switch 522 is turned on and a voltage signal is output from the signal inverting circuit 521 to the amplitude detection circuit 523. When the level of the voltage waveform 74a is high, the switch 522 is turned off and no voltage is input into the amplitude detection circuit 523. The waveform 75b denotes a voltage output waveform of the switch 522. A voltage represented by the voltage output waveform 75b is input into the amplitude detection circuit 523. Since the voltage represented by the voltage output waveform 75b does not vary, the voltage is connected to the ground potential. Accordingly, the amplitude detection circuit 523 outputs nothing as shown in the voltage output waveform 76b. The voltage output waveform 76b is input into the non-inverting input terminal of the second comparing circuit 540. The second comparing circuit 540 compares a voltage represented by the voltage output waveform 76b with the second reference voltage 541. Since the level of the voltage output waveform 76b is lower than that of the second reference voltage 541, the second comparing circuit 540 outputs nothing. The voltage output waveform 77b having no signal is input into the flip-flop circuit 552 via the OR gate 551.

[Fault Detection Process in FIG. 2(b)]

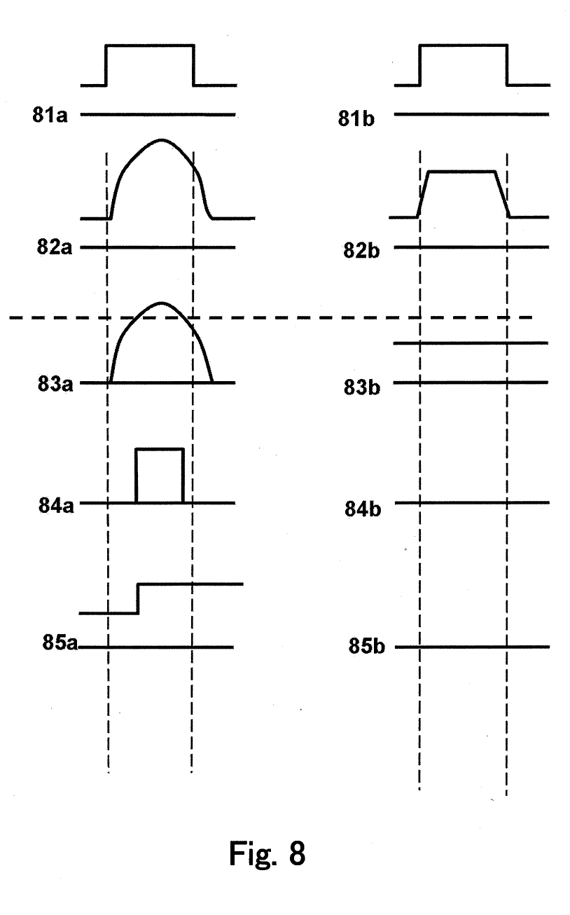

FIG. 8 is a diagram describing a process of detecting the fault shown in FIG. 2(b). Waveforms shown in FIG. 8 will be described in the following using the corresponding blocks shown in FIG. 5. Voltage waveforms 81a to 85a are obtained when the fault shown in FIG. 2(b) occurs.

The voltage waveform 81a is output from the receiving circuit 11. The voltage waveform 82a denotes a voltage at the connection point between the second line and the terminating resistor 3b. The voltage waveform 82a is input into the peak detecting circuit 510, so that the voltage waveform 83a is output. The peak detecting circuit 510 removes a bias voltage component from the voltage output waveform 82a so as to obtain only an amplitude component and outputs the obtained voltage output waveform 83a. The voltage output waveform 83a is input into the non-inverting input terminal of the first comparing circuit 530. The first comparing circuit 530 compares a voltage represented by the voltage output waveform 83a with the first reference voltage 531, and outputs the voltage output waveform 84a. The voltage output waveform 84a is input into the flip-flop circuit 552 via the OR gate 551. The flip-flop circuit 552 maintains the received signal, and outputs the voltage output waveform 85a.

Voltage waveforms 81b to 85b are obtained in a normal state in FIG. 2(b). The voltage waveform 81b is output from the receiving circuit 11. The voltage waveform 82b denotes a voltage at the connection point between the second line and the terminating resistor 3b. The voltage waveform 82b is input into the peak detecting circuit 510, so that the voltage waveform 83b (no signal) is output. The peak detecting circuit 510 removes a bias voltage component from the voltage waveform 82b. However, since an amplitude component does not vary in the voltage waveform 82b, the peak detecting circuit 510 outputs no voltage. Accordingly, in the subsequent circuits, no signal is output.

Thus, the first embodiment has been described with reference to the line fault detection circuit 500. A difference between the line fault detection circuits 500 and 600 is that the line fault detection circuit 500 detects a fault in the second line and the line fault detection circuit 600 detects a fault in the first line. Accordingly, in the line fault detection circuit 500, the voltage of the second line is input into the peak detecting circuit 510 and the signal inverting circuit 521 included in the trough detecting circuit 520. In the line fault detection circuit 600, the voltage of the first line is input into the peak detecting circuit 610 and a signal inverting circuit 621 included in the trough detecting circuit 620.

### Second Embodiment

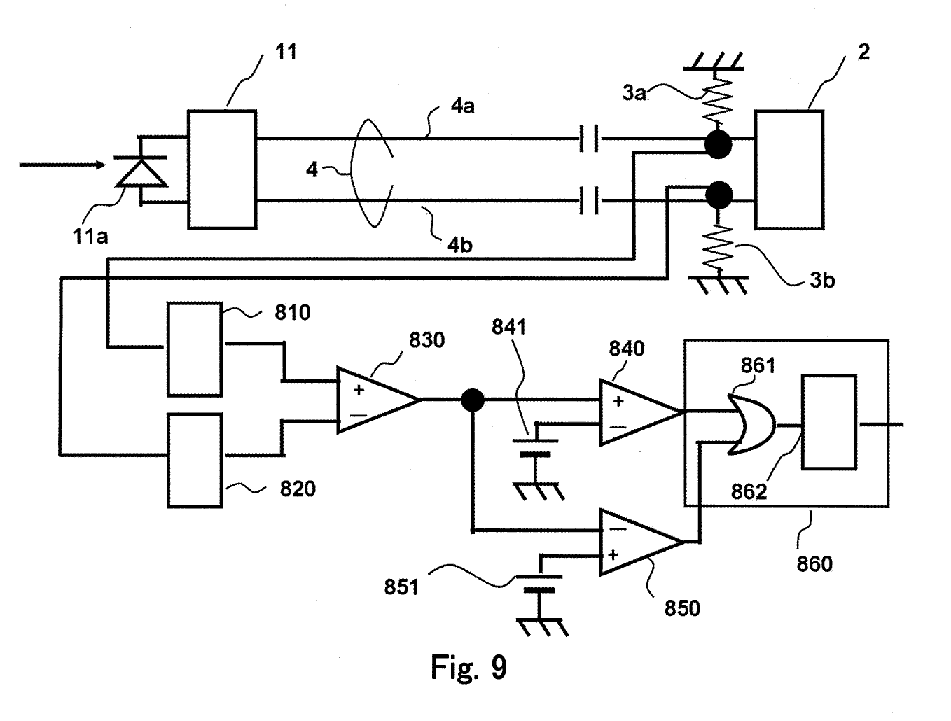

As is apparent from the voltage waveforms shown in FIGS. 3 and 4, if a fault occurs at a terminating resistor, a voltage value different from a usual voltage value is obtained regardless of whether the terminating resistor is short-circuited or disconnected. Here, it is assumed that the other line is in a normal state. The line fault can be detected by comparing voltage conditions of lines. The specific configuration of a line fault detection circuit for comparing voltage conditions of lines is shown in FIG. 9. The line fault detection circuit includes first voltage amplitude detecting circuit, second voltage amplitude detecting circuit, first comparing circuit, second comparing circuit, third comparing circuit, and signal maintaining circuit. The configurations of these circuits will be individually described in the following. In FIG. 9, the same reference numerals are used for components having the same functions as those of FIG. 1 so as to avoid repeated explanation.

[First Voltage Amplitude Detecting Circuit]

First voltage amplitude detecting circuit 810 is configured with the circuit shown in FIG. 6. A voltage is input from the first line 4a to an input portion of the first voltage amplitude detecting circuit 810. A bias potential included in the voltage waveform that has been input threreinto is removed, and an amplitude voltage is then output.

[Second Voltage Amplitude Detecting Circuit]

A second voltage amplitude detecting circuit 820 is configured with the circuit shown in FIG. 6. A voltage is input from the second line 4b to an input portion of the second voltage amplitude detecting circuit 820. A bias potential included in the voltage waveform that has been input thereinto is removed, and an amplitude voltage is then output.

[First Comparing Circuit]

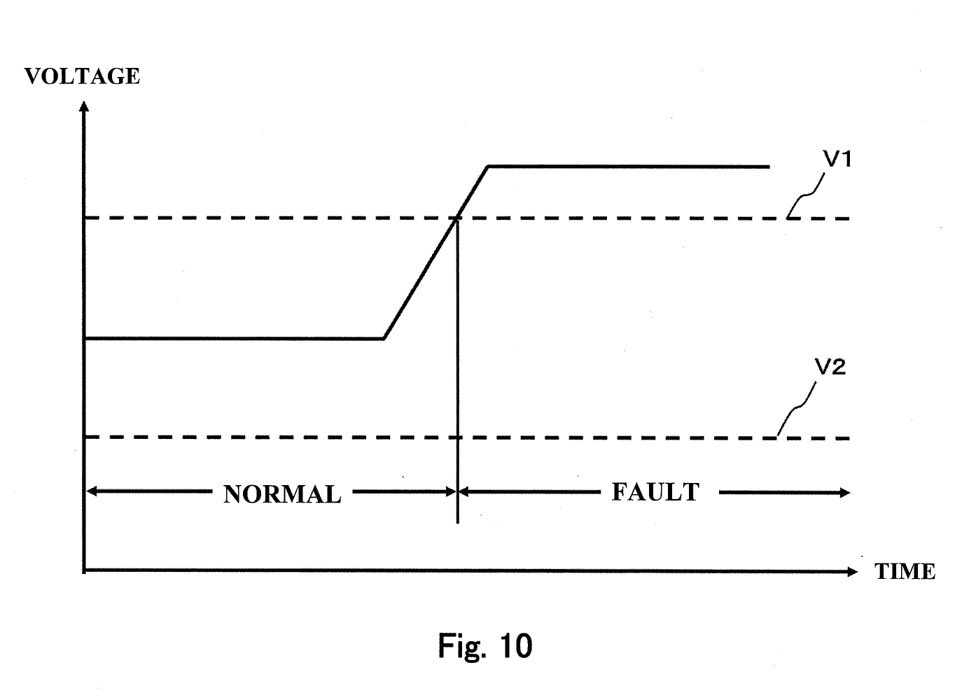

First comparing circuit 830 is configured with an operational amplifier. The output of the first voltage amplitude detecting circuit is input into the non-inverting input terminal of the operational amplifier. The output of the second voltage amplitude detecting circuit is input into the inverting input terminal of the operational amplifier. The operational amplifier compares values of voltages output from the first voltage amplitude detecting circuit and the second voltage amplitude detecting circuit, and outputs the comparison result from the output terminal thereof. The output characteristics of the output terminal are shown in FIG. 10.

[Second Comparing Circuit]

Second comparing circuit 840 is configured with an operational amplifier. The output of the first comparing circuit is input into the non-inverting input terminal of the operational amplifier. A first reference voltage is input into the inverting input terminal of the operational amplifier. The value of the first reference voltage is a value of a voltage V1 shown in FIG. 10. When the voltage of the first comparing circuit is larger than the first reference voltage V1, a voltage is output from the output terminal of the second comparing circuit 840.

[Third Comparing Circuit]

Third comparing circuit 850 is configured with an operational amplifier. The output of the first comparing circuit is input into the inverting input terminal of the operational amplifier. A second reference voltage is input into the non-inverting input terminal of the operational amplifier. The value of the second reference voltage is a value of a voltage V2 shown in FIG. 10. When the voltage of the first comparing circuit is lower than the second reference voltage V2, a voltage is output from the output terminal of the third comparing circuit 850.

[Signal Maintaining Circuit]

Signal maintaining circuit 860 receives the outputs of the second comparing circuit 840 and the third comparing circuit 850. More specifically, signals output from the second comparing circuit 840 and the third comparing circuit 850 are input into an OR gate 861. When the OR gate 861 receives high-level signals from the second comparing circuit 840 and the third comparing circuit 850, it sets the output thereof to a high level. The output of the OR gate 861 is input into a flip-flop circuit 862. The flip-flop circuit 862 maintains the high-level output of the OR gate 861, and transmits the maintained output.

According to the present invention, a line fault can be detected by comparing a voltage waveform of a line with a reference voltage even when the line fault occurs at a terminating resistor that is disposed between the line and the ground so as to achieve impedance matching of a differential transmission line composed of two transmission lines for which impedance control is required. Furthermore, a line fault can be detected by comparing voltage waveforms of lines.

According to the present embodiments, a line fault can be detected even when the line fault occurs at a terminating resistor that is disposed between a line and the ground so as to achieve impedance matching of a differential transmission line composed of two transmission lines for which impedance control is required.

What is claimed is:

1. A line trouble detecting circuit for detecting a line trouble of a differential pair, the differential pair for transmitting a differential signal with a first line and a second line earthed via termination resistors, respectively, the line trouble detecting circuit comprising:
a peak detecting circuit for detecting a peak voltage of an amplitude of the one of the differential signal;
a first comparison circuit for comparing an output of the peak detector and a first reference voltage;
a bottom detecting circuit for detecting bottom voltage of the amplitude of the one of the differential signal;
a second comparison circuit for comparing an output of the bottom detecting circuit and a second reference voltage; and
a signal keeping circuit keeping a signal from the first comparison circuit or the second comparison circuit.

2. The A line trouble detecting circuit of claim 1 wherein the peak detecting circuit comprises an input terminal, a output terminal, a first diode having an anode connected with the input terminal and a cathode connected with the output terminal, and a second diode having a cathode connected with the input terminal and an anode connected with earth.

3. The line trouble detecting circuit of claim 1 wherein the bottom detecting circuit comprises, a first circuit for inverting first signal voltage from the first line, a second circuit for switching the first signal voltage by second signal voltage form the second line, and an amplitude detection circuit for removing a base component of the switched first signal from the second circuit.

4. A line trouble detecting circuit for detecting a line trouble of a differential pair, the differential pair for transmitting a differential signal by a first line and a second line earthed via a termination resistor, respectively, the line trouble detecting circuit comprising:
a first voltage magnitude detecting circuit for detecting a voltage magnitude;
a second voltage magnitude detecting circuit for detecting a voltage magnitude; a first comparison circuit for comparing outputs of the first and second voltage magnitude detecting circuit;
a second comparison circuit for comparing an output of the first comparison circuit and a first reference voltage:
a third comparison circuit for comparing an output of the first comparison circuit and a second reference voltage
a signal keeping circuit keeping a signal from the second comparison circuit or the third comparison circuit.

5. The line trouble detecting circuit of claim 4 wherein the first voltage magnitude detecting circuit and the second voltage magnitude detecting circuit comprise an input terminal, a output terminal, a first diode having an anode connected with the input terminal and a cathode connected with the output terminal, and a second diode having a cathode connected with the input terminal and an anode connected with earth.
